(19) United States
(12) Patent Application Publication
(10) Pub. No.: US 2026/0190296 A1
(43) Pub. Date: Jul. 2, 2026

(54) HEAT DISSIPATION DEVICE OF STORAGE SERVER

(71) Applicant: Celestica Technology Consultancy (Shanghai) Co. Ltd, Shanghai (CN)

(72) Inventors: Wenhao Li, Shanghai (CN); Jinbin Qiu, Shanghai (CN); Renyong Yu, Shanghai (CN); Yaoyin Fan, Shanghai (CN)

(21) Appl. No.: 19/331,922

(22) Filed: Sep. 17, 2025

(30) Foreign Application Priority Data
Dec. 31, 2024 (CN) 2024119986853

(51) Int. Cl. H05K 7/20

(52) U.S. Cl. CPC H05K 7/20727

(57) ABSTRACT

The present disclosure provides a heat dissipation device of a storage server, which includes a first heat-dissipation air channel, a second heat-dissipation air channel, and a third heat-dissipation air channel. The first heat-dissipation air channel is arranged at a front of the storage server to dissipate heat for a first heat-dissipation area at the front of the storage server; the second heat-dissipation air channel is arranged at two sides of the storage server to dissipate heat for a second heat-dissipation area at a rear of the storage server; the third heat-dissipation air channel is arranged at a bottom of the storage server to dissipate heat for the second heat-dissipation area at the rear of the storage server.

### FIELD OF TECHNOLOGY

The present disclosure belongs to the technical field of heat dissipation, in particular, to a heat dissipation device of a storage server.

### BACKGROUND

Heat dissipation of a storage server is a key factor to ensure its stable operation and prolong its service life. Existing heat dissipation schemes for the storage server mainly include air-cooling heat dissipation and liquid-cooling heat dissipation. The air-cooling heat dissipation is to increase air flowing and help discharge heat in time by providing efficient chassis fans and radiator fans, while the liquid-cooling heat dissipation is generally to take away heat through heat conduction by indirect contact between cooling liquid and heating components of the server. For the air-cooling heat dissipation, it mainly relies on air flowing to take away heat, with heat dissipation efficiency being limited by air thermal conductivity. Therefore, it has become a problem that needs to be solved urgently in this field to improve efficiency of the air-cooling heat dissipation.

### SUMMARY

The present disclosure provides a heat dissipation device of a storage server.

The heat dissipation device includes a first heat-dissipation air channel, a second heat-dissipation air channel, and a third heat-dissipation air channel.

The first heat-dissipation air channel is arranged at a front of the storage server to dissipate heat for a first heat-dissipation area at the front of the storage server.

The second heat-dissipation air channel is arranged at two sides of the storage server to dissipate heat for a second heat-dissipation area at a rear of the storage server.

The third heat-dissipation air channel is arranged at a bottom of the storage server to dissipate heat for the second heat-dissipation area at the rear of the storage server.

In an embodiment of the present disclosure, the heat dissipation device further includes an air guide structure. The air guide structure is arranged between the first heat-dissipation area and the second heat-dissipation area to separate the first heat-dissipation area from the second heat-dissipation area, and an airflow of the first heat-dissipation air channel is collected in an isolation area through the air guide structure after dissipating heat for the first heat-dissipation area and is discharged outside of the storage server through the isolation area.

In an embodiment of the present disclosure, the isolation area includes a first isolation plate and a second isolation plate, which are arranged in parallel at a middle of the second heat-dissipation area to form the isolation area at the middle of the second heat-dissipation area. The isolation area is communicated with the first heat-dissipation area at a front of the isolation area, and the isolation area is communicated with a back panel of the storage server at a rear of the isolation area.

In an embodiment of the present disclosure, the airflow of the first heat-dissipation air channel enters the isolation area at a communication part of the isolation area and the first heat-dissipation area after dissipating heat for the first heat-dissipation area, and is discharged outside of the storage server from a communication part of the isolation area and the back panel.

In an embodiment of the present disclosure, an isolation air outlet is provided at a connection of the air guide structure and the isolation area, and the airflow of the first heat-dissipation air channel enters the isolation area through the isolation air outlet after dissipating heat for the first heat-dissipation area, and is discharged outside of the storage server from the communication part of the isolation area and the back panel.

In an embodiment of the present disclosure, the air guide structure includes a first air guide plate and a second air guide plate, and a first isolation air outlet is provided at a connection of the first air guide plate and the first isolation plate, and a second isolation air outlet is provided at a connection of the second air guide plate and the second isolation plate.

In an embodiment of the present disclosure, an airflow of the second heat-dissipation air channel and an airflow of the third heat-dissipation air channel are collected behind the air guide structure and dissipate heat for the second heat-dissipation area.

In an embodiment of the present disclosure, an air channel accommodating space is provided at two sides of the storage server, and the air channel accommodating space is provided with an opening inward, and the second heat-dissipation air channel is arranged in the air channel accommodating space and the airflow of the second heat-dissipation air channel is output through the opening.

In an embodiment of the present disclosure, a PCB board is provided at a bottom of the storage server, the third heat-dissipation air channel is arranged below the PCB board, and the airflow of the third heat-dissipation air channel is output through a sandwich space formed by the PCB board and the bottom plate of the storage server.

In an embodiment of the present disclosure, the heat dissipation device further includes a fan, and the fan provides airflows for the first heat-dissipation air channel, the second heat-dissipation air channel and the third heat-dissipation air channel.

The heat dissipation device of the storage server in the present disclosure has following beneficial effects. A heat dissipation problem of hard disk arrays in the storage server can be solved, a maximum temperature of the storage server can be effectively reduced, and a number of supported hard disks and maximum power consumption can be increased.

### BRIEF DESCRIPTION OF DRAWINGS

FIG. 1 shows a schematic structural view of a heat dissipation device of a storage server according to an embodiment of the present disclosure.

FIG. 2 shows a top view of a heat dissipation device of a storage server according to an embodiment of the present disclosure.

FIG. 3 shows a side view of a heat dissipation device of a storage server according to an embodiment of the present disclosure.

FIG. 4 shows a front view of a heat dissipation device of a storage server according to an embodiment of the present disclosure.

FIG. 5 shows a schematic structural view of a heat dissipation device of a storage server according to an embodiment of the present disclosure.

FIG. 6 shows a schematic structural view of a heat dissipation device of a storage server according to an embodiment of the present disclosure.

Reference Numerals

| | |
|---|---|
| 11 | First Heat-Dissipation Air Channel |
| 12 | Second Heat-Dissipation Air Channel |
| 13 | Third Heat-Dissipation Air Channel |
| 14 | Air Guide Structure |
| 141 | First Air Guide Plate |
| 142 | Second Air Guide Plate |
| 143 | Isolation Air Outlet |
| 1431 | First Isolation Air Outlet |
| 1432 | Second Isolation Air Outlet |
| 15 | Isolation Area |
| 151 | First Isolation Plate |
| 152 | Second Isolation Plate |
| 21 | First Heat-dissipation Area |
| 22 | Second Heat-dissipation Area |
| 23 | Air Channel Accommodating Space |
| 231 | Opening |
| 24 | PCB Board |
| 25 | Sandwich Space |

### DETAILED DESCRIPTION

Implementations of the present disclosure are illustrated in the following through specific examples, and other advantages and effects of the disclosure can be easily understood by those skilled in the art from contents disclosed in this specification. The present disclosure can also be implemented or applied through other different specific embodiments, and details in this specification can be modified or changed based on different viewpoints and applications without departing from the spirit of the present disclosure. It should be noted that following embodiments and features in the embodiments can be combined mutually in the case of no conflict.

It should be noted that views provided in the following embodiments only illustrate a basic idea of the present disclosure in a schematic way, and thus only components related to the present disclosure are shown in the views instead of being drawn according to a number, shapes and sizes of the components in actual implementations. In actual implementations, modes, number and scales of the components can be changed arbitrarily, and a layout of the components may be more complicated.

In addition, descriptions involving “first”, “second” or the like in the present disclosure are only intended for descriptive purposes, and cannot be understood as indicating or implying a relative importance, or implicitly indicating a number of indicated technical features. Therefore, features defined with “first” and “second” can include at least one of the features explicitly or implicitly. In addition, technical schemes of respective embodiments can be combined with each other, which must be based on enabling of realization by an ordinary skilled in the art. When combination of technical schemes is contradictory or impossible to be realized, it should be considered that such combination of technical schemes does not exist and either is not within the protection scope claimed in the present disclosure.

Air-cooling heat dissipation, as a main way of heat dissipation of a storage server, helps heat in the server be discharged through air flowing. In general design, after cold air enters from a front of a chassis and gradually flows through each row of hard disks, temperature of hard disks in rear rows may be higher than that in front rows, and then the air can be discharged behind the chassis. This means that when the airflow reaches a back of the server, it carries a lot of heat, and thus it is difficult to effectively dissipate heat of last few rows of or row of hard disks. At this time, temperature of the last row or rows of hard disks is highest, which becomes a bottleneck of heat dissipation of the storage server, which greatly restricts a number of hard disks supported by a product and maximum power consumption.

In order to at least solve above problems, a heat dissipation device of a storage server is provided in an embodiment of the disclosure, which can improve air-cooling heat dissipation efficiency and effectively realize heat dissipation for the whole storage server.

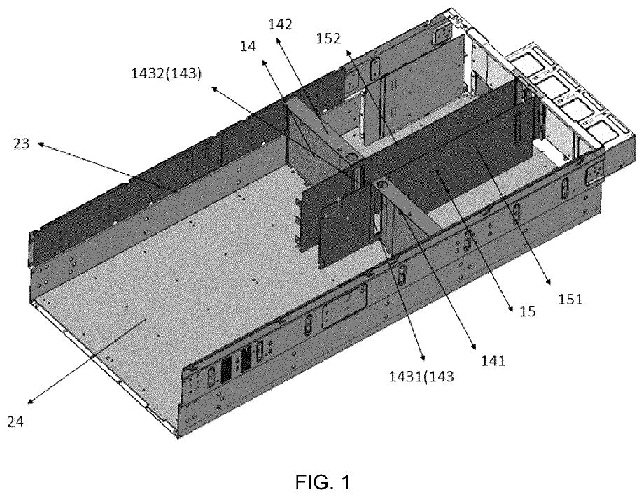

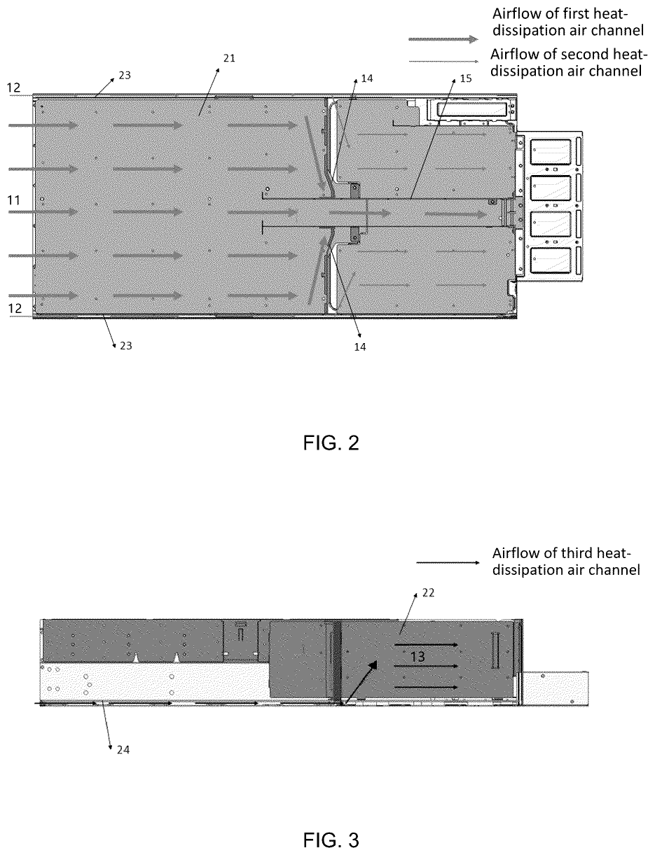

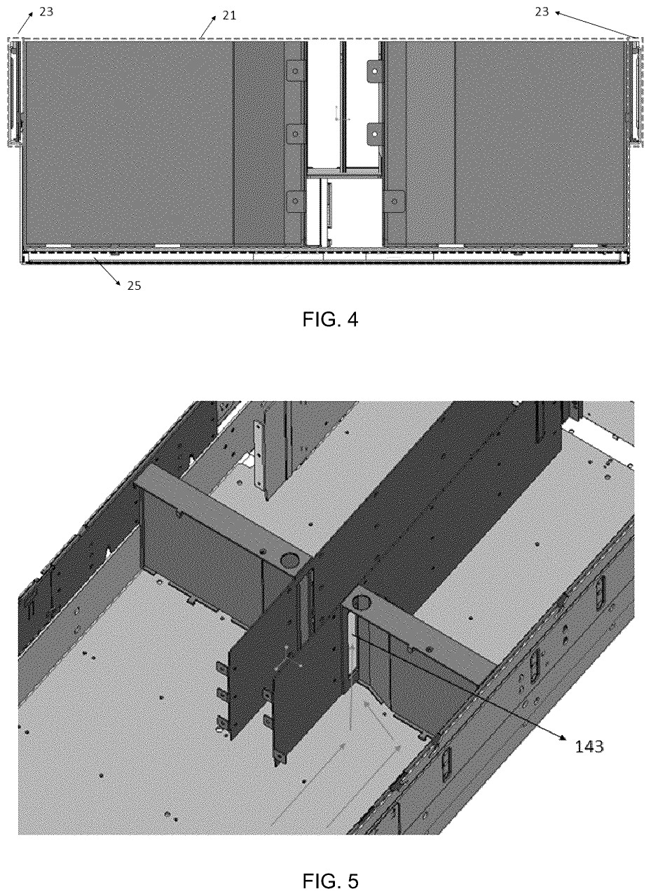

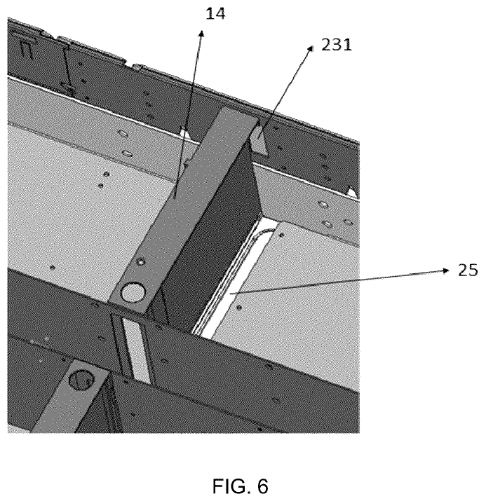

Referring to FIGS. 1 to 4, a heat dissipation device of a storage server provided in an embodiment of the present disclosure includes a first heat-dissipation air channel 11, a second heat-dissipation air channel 12 and a third heat-dissipation air channel 13.

The first heat-dissipation air channel 11 is arranged at the front of the storage server to dissipate heat for a first heat-dissipation area 21 at the front of the storage server. The second heat-dissipation air channel 12 is arranged at two sides of the storage server to dissipate heat for a second heat-dissipation area 22 at the rear of the storage server. The third heat-dissipation air channel 13 is arranged at a bottom of the storage server to dissipate heat for the second heat-dissipation area 22 at the rear of the storage server.

Further, the heat dissipation device 1 of a storage server further includes a fan, and the fan provides airflows for the first heat-dissipation air channel 11, the second heat-dissipation air channel 12 and the third heat-dissipation air channel 13. That is, the fan provides independent airflows, which are divided into three airflows through the first heat-dissipation air channel 11, the second heat-dissipation air channel 12 and the third heat-dissipation air channel 13 to dissipate heat for different areas of the storage server, thus ensuring that the hard disks in a rear area of the storage server can be effectively air-cooling dissipated.

Referring to FIGS. 1 to 4, the heat dissipation device 1 of the storage server further includes an air guide structure 14.

The air guide structure 14 is arranged between the first heat-dissipation area 21 and the second heat-dissipation area 22 to separate the first heat-dissipation area 21 from the second heat-dissipation area 22, and an airflow of the first heat-dissipation air channel 11 is collected in an isolation area 15 through the air guide structure 14 after dissipating heat for the first heat-dissipation area 21 and is discharged outside of the storage server through the isolation area 15.

Referring still to FIGS. 1 to 4, the isolation area 15 includes a first isolation plate 151 and a second isolation plate 152. The first isolation plate 151 and the second isolation plate 152 are arranged in parallel at a middle of the second heat-dissipation area 22 to form the isolation area 15 at the middle of the second heat-dissipation area 22. The isolation area 15 is communicated with the first heat-dissipation area 21 at a front of the isolation area, and the isolation area 15 is communicated with a back panel of the storage server at a rear of the isolation area.

Specifically, the airflow of the first heat-dissipation air channel 11 enters the isolation area 15 at a communication part of the isolation area 15 and the first heat-dissipation area 21 after dissipating heat for the first heat-dissipation area 21, and is discharged outside of the storage server from a communication part of the isolation area 15 and the back panel.

Specifically, referring still to FIGS. 1 to 4, an isolation air outlet 143 is provided at a connection of the air guide structure 14 and the isolation area 15, and the airflow of the first heat-dissipation air channel 11 enters the isolation area 15 through the isolation air outlet 143 after dissipating heat for the first heat-dissipation area 21, and is discharged outside of the storage server from the communication part of the isolation area 15 and the back panel.

Referring still to FIGS. 1 to 4, the air guide structure 14 includes a first air guide plate 141 and a second air guide plate 142, and a first isolation air outlet 1431 is provided at a connection of the first air guide plate 141 and the first isolation plate 151, and a second isolation air outlet 1432 is provided at a connection of the second air guide plate 142 and the second isolation plate 152.

When the fan is started, a part of the airflow may enter the first heat-dissipation air channel 11. At this time, the airflow of the first heat-dissipation air channel 11 can dissipate heat for the first heat-dissipation area 21 at the front of the storage server, for example, for first to fifth rows of hard disks. After passing through the fifth row of hard disks, the airflow of the first heat-dissipation air channel 11 can enter the isolation area 15 from the communication part of the isolation area 15 and the first heat-dissipation area 21, and airflows not directly facing the communication part can be drained to the isolation air outlet 143 through the air guide structure 14 so as to enter the isolation area 15 through the isolation air outlet 143.

Furthermore, in fact, a fan is provided at the communication part of the isolation area 15 and the back panel of the storage server. The fan can quickly draw air in the isolation area 15, so as to discharge gas with heat outside of the storage server after heat dissipation.

Further, when the fan is started, there can be an airflow entering the second heat-dissipation air channel 12 and the third heat-dissipation air channel 13 to air-cooling dissipate rear hard disks. An airflow of the second heat-dissipation air channel 12 and an airflow of the third heat-dissipation air channel 13 are collected behind the air guide structure 14 and dissipate heat for the second heat-dissipation area 22. That is, the airflows of the second heat-dissipation air channel 12 and the third heat-dissipation air channel 13 do not dissipate heat for the first heat-dissipation area 21 at the front of the storage server, and thus low temperature can be kept to take away heat at the rear. For example, when the storage server has 8 rows of hard disks, the hard disk array is divided into two parts, namely, the first heat-dissipation area 21 (first to fifth rows of hard disks) and the second heat-dissipation area 22 (sixth to eighth rows of hard disks). In this case, the airflows of the second heat-dissipation air channel 12 and the third heat-dissipation air channel 13 are collected behind the air guide structure 14 to dissipate heat for the sixth to eighth rows of hard disks.

Specifically, referring still to FIGS. 1 to 4, an air channel accommodating space 23 is provided at two sides of the storage server, and the air channel accommodating space 23 is provided with an opening 231 inward, and the second heat-dissipation air channel 12 is arranged in the air channel accommodating space 23 and the airflow of the second heat-dissipation air channel 12 is output through the opening 231. That is, when the fan is started, a part of the airflow enters the second heat-dissipation air channel 12, directly flows behind the air guide structure 14, and is output to the second heat-dissipation area 22 through the opening 231 for air-cooling heat dissipation.

Further, referring still to FIGS. 1 to 4, the air duct accommodation space 23 is located in upper halves of two side plates of the storage server. That is, in fact, the second heat-dissipation air channel 12 is arranged in the upper halves at both sides of the storage server and outputs outwards through the opening 231. In this case, due to a principle of cold air sinking, the airflow of the second heat-dissipation air channel 12 may flow downward, so as to realize air-cooling heat dissipation of the second heat-dissipation area 22.

Specifically, referring still to FIGS. 1 to 4, a PCB board 24 is provided at a bottom of the storage server, the third heat-dissipation air channel 13 is arranged below the PCB board 24, and the airflow of the third heat-dissipation air channel 13 is output through a sandwich space 25 formed by the PCB board 24 and the bottom plate of the storage server. In fact, the PCB board 24 is provided at the bottom of the storage server, and the third heat-dissipation air channel 13 is located below the PCB board 24, and because the PCB board 24 and the bottom of the storage server are not firmly attached to each other, when the fan is started, a part of the airflow enters the third heat-dissipation air channel 13, directly flows behind the air guide structure 14, and is output through the sandwich space 25 formed by the PCB board 24 and the bottom plate of the storage server.

Further, both the second heat-dissipation air channel 12 and the third heat-dissipation air channel 13 dissipate heat for the second heat-dissipation area 22 at the rear of the storage server. The second heat-dissipation air channel 12 is arranged in the upper halves at both sides of the storage server, and the third heat-dissipation air channel 13 is arranged at the bottom of the storage server. The airflow of the second heat-dissipation air channel 12 sinks after being output so as to dissipate heat for rear rows of hard disks, while the airflow of the third heat-dissipation air channel 13 can effectively take away heat below the rear rows of hard disks after being output from the bottom. That is, combination of the second heat-dissipation air channel 12 and the third heat-dissipation air channel 13 can effectively realize all-round heat dissipation of the second heat-dissipation area 22 at the rear of the storage server.

Further, the airflows of the second heat-dissipation air channel 12 and the third heat-dissipation air channel 13 may be discharged outside of the storage server through the fan arranged behind the storage server after dissipating heat for the second heat-dissipation area 22 at the rear of the storage server.

As described above, the heat dissipation device of the storage server provided in the disclosure can divide the airflow into the first heat-dissipation air channel, the second heat-dissipation air channel and the third heat-dissipation air channel. The first heat-dissipation air channel is arranged at the front of the storage server to dissipate heat for the first heat-dissipation area at the front of the storage server, and the airflow of the first heat-dissipation air channel is drained through the air guide structure to or directly enters the isolation area after dissipating heat, and then is discharged outside the storage server through the isolation area. The second heat-dissipation air channel is arranged at both sides of the storage server through the air channel accommodating space, so that the airflow of the second heat-dissipation air channel directly flows behind the air guide structure and is output through the opening to dissipate heat for the second heat-dissipation area at the rear. The third heat-dissipation air channel is arranged below the PCB at the bottom, and the airflow of the third heat-dissipation air channel directly flows to the rear of the air guide structure, and is output through the sandwich space between the PCB and the bottom plate to dissipate heat for the second heat-dissipation area at the rear. It can be seen that air-cooling heat dissipation in different areas is realized through different air channel design, so that areas at the rear of the storage server can also receive cold air and realize efficient heat dissipation.

Descriptions of processes or structures corresponding to above figures have their own emphases. For parts not detailed in a certain process or structure, reference can be made to related descriptions of other processes or structures.

The above embodiments only illustrate the principle and efficacy of the present disclosure, but are not intended to limit the present disclosure. The above embodiments can be modified or changed by anyone familiar with this technology without departing from the spirit and scope of the present disclosure. Therefore, all of equivalent modifications or changes made by persons with ordinary knowledge in this art without departing from the spirit and technical ideas disclosed in the present disclosure should still be encompassed by claims of the present disclosure.

1.-10. (canceled)

11. A heat dissipation device comprising:
a first heat-dissipation air channel;
a second heat-dissipation air channel; and
a third heat-dissipation air channel,
wherein the first heat-dissipation air channel is arranged at a front of a storage server to dissipate heat for a first heat-dissipation area at the front of the storage server;
wherein the second heat-dissipation air channel is arranged at two sides of the storage server to dissipate heat for a second heat-dissipation area at a rear of the storage server; and
wherein the third heat-dissipation air channel is arranged at a bottom of the storage server to dissipate heat for the second heat-dissipation area at the rear of the storage server.

12. The heat dissipation device of claim 11,
wherein the heat dissipation device further comprises an air guide structure,
wherein the air guide structure is arranged between the first heat-dissipation area and the second heat-dissipation area to separate the first heat-dissipation area from the second heat-dissipation area, and
wherein an airflow of the first heat-dissipation air channel is collected in an isolation area through the air guide structure after dissipating heat for the first heat-dissipation area and is discharged outside of the storage server through the isolation area.

13. The heat dissipation device of claim 12,
wherein the isolation area comprises a first isolation plate and a second isolation plate arranged in parallel at a middle of the second heat-dissipation area to form the isolation area at the middle of the second heat-dissipation area,
wherein the isolation area is communicated with the first heat-dissipation area at a front of the isolation area, and
wherein the isolation area is communicated with a back panel of the storage server at a rear of the isolation area.

14. The heat dissipation device of claim 13,
wherein the airflow of the first heat-dissipation air channel enters the isolation area at a communication part of the isolation area and the first heat-dissipation area after dissipating heat for the first heat-dissipation area, and is discharged outside of the storage server from a communication part of the isolation area and the back panel.

15. The heat dissipation device of claim 13,
wherein an isolation air outlet is provided at a connection of the air guide structure and the isolation area, and
wherein the airflow of the first heat-dissipation air channel enters the isolation area through the isolation air outlet after dissipating heat for the first heat-dissipation area, and is discharged outside of the storage server from a communication part of the isolation area and the back panel.

16. The heat dissipation device of claim 15,
wherein the air guide structure comprises a first air guide plate and a second air guide plate, wherein a first isolation air outlet is provided at a connection of the first air guide plate and the first isolation plate, and
wherein a second isolation air outlet is provided at a connection of the second air guide plate and the second isolation plate.

17. The heat dissipation device of claim 12,
wherein an airflow of the second heat-dissipation air channel and an airflow of the third heat-dissipation air channel are collected behind the air guide structure and dissipate heat for the second heat-dissipation area.

18. The heat dissipation device of claim 11,
wherein an air channel accommodating space is provided at two sides of the storage server, and the air channel accommodating space is provided with an opening inward, and
wherein the second heat-dissipation air channel is arranged in the air channel accommodating space and an airflow of the second heat-dissipation air channel is output through the opening.

19. The heat dissipation device of claim 17,
wherein a PCB board is provided at a bottom of the storage server, the third heat-dissipation air channel is arranged below the PCB board, and
wherein the airflow of the third heat-dissipation air channel is output through a sandwich space formed by the PCB board and a bottom plate of the storage server.

20. The heat dissipation device of claim 11,
wherein the heat dissipation device further comprises a fan, the fan providing airflows for the first heat-dissipation air channel, the second heat-dissipation air channel and the third heat-dissipation air channel.

21. The heat dissipation device of claim 11,
wherein the heat dissipation device further comprises an air guide structure.

22. The heat dissipation device of claim 21, wherein the air guide structure is arranged between the first heat-dissipation area and the second heat-dissipation area.

23. The heat dissipation device of claim 22,
wherein an airflow of the first heat-dissipation air channel is collected in an isolation area through the air guide structure after dissipating heat for the first heat-dissipation area and is discharged outside of the storage server through the isolation area,
wherein the isolation area comprises a first isolation plate and a second isolation plate arranged in parallel at a middle of the second heat-dissipation area to form the isolation area at the middle of the second heat-dissipation area,
wherein the isolation area is communicated with the first heat-dissipation area at a front of the isolation area, and
wherein the isolation area is communicated with a back panel of the storage server at a rear of the isolation area.

24. The heat dissipation device of claim 23,
wherein the airflow of the first heat-dissipation air channel enters the isolation area at a communication part of the isolation area and the first heat-dissipation area after dissipating heat for the first heat-dissipation area, and is discharged outside of the storage server from a communication part of the isolation area and the back panel.

25. The heat dissipation device of claim 23,
wherein an isolation air outlet is provided at a connection of the air guide structure and the isolation area, and
wherein the airflow of the first heat-dissipation air channel enters the isolation area through the isolation air outlet after dissipating heat for the first heat-dissipation area, and is discharged outside of the storage server from a communication part of the isolation area and the back panel.

26. The heat dissipation device of claim 25,
wherein the air guide structure comprises a first air guide plate and a second air guide plate, wherein a first isolation air outlet is provided at a connection of the first air guide plate and the first isolation plate, and
wherein a second isolation air outlet is provided at a connection of the second air guide plate and the second isolation plate.

27. The heat dissipation device of claim 22,
wherein an airflow of the second heat-dissipation air channel and an airflow of the third heat-dissipation air channel are collected behind the air guide structure and dissipate heat for the second heat-dissipation area.

28. The heat dissipation device of claim 21,
wherein an air channel accommodating space is provided at two sides of the storage server, and the air channel accommodating space is provided with an opening inward, and
wherein the second heat-dissipation air channel is arranged in the air channel accommodating space and an airflow of the second heat-dissipation air channel is output through the opening.

29. The heat dissipation device of claim 28,
wherein a PCB board is provided at a bottom of the storage server, the third heat-dissipation air channel is arranged below the PCB board, and
wherein the airflow of the third heat-dissipation air channel is output through a sandwich space formed by the PCB board and a bottom plate of the storage server.

30. The heat dissipation device of claim 21,
wherein the heat dissipation device further comprises a fan, the fan providing airflows for the first heat-dissipation air channel, the second heat-dissipation air channel and the third heat-dissipation air channel.
